(19) United States
(12) Patent Application Publication
(10) Pub. No.: US 2014/0246074 A1
(43) Pub. Date: Sep. 4, 2014

(54) SOLAR MODULE WITH RIBBON CABLE, AND A METHOD FOR THE MANUFACTURE OF SAME

(71) Applicant: SAINT-GOBAIN GLASS FRANCE, Courbevoie (FR)

(72) Inventors: Matthias Doech, Muenchen (DE); Robert Gass, Herzogenrath (DE); Thomas Happ, Muenchen (DE); Jan Boris Philipp, Muenchen (DE); Mitja Rateiczak, Wuerselen (DE); Walter Stetter, Illertissen (DE); Lars Voland, Ottobrunn (DE)

(73) Assignee: SAINT-GOBAIN GLASS FRANCE, Courbevoie (FR)

(21) Appl. No.: 14/350,353

(22) PCT Filed: Oct. 18, 2012
(86) PCT No.: PCT/EP2012/070706

§ 371 Date: Apr. 7, 2014

(30) Foreign Application Priority Data
Oct. 19, 2011 (EP) 11185732.2

(51) Int. Cl. H01L 31/048; H01R 43/00

(52) U.S. Cl. CPC H01L 31/0485; H01R 43/00
USPC 136/244; 29/857

(57) ABSTRACT

A solar module, more particularly a thin-film solar module having a plurality of solar cells connected in series for the photovoltaic generation of power, is described. The solar module has two voltage terminals of opposite polarity, which are each connected to an external surface of the module. Each of the two leads is electrically connected to a separate terminal device. Each of the two terminal housings is attached to the outer surface of the module. The two leads are electrically interconnected through a flyback diode, and the two terminal devices are electrically connected by a ribbon cable that is arranged between the two terminal housings and attached to the external surface of the module. A manufacturing method for the solar module is also described.

Photovoltaic layer systems for the direct conversion of sunlight into electrical energy are well known. They are commonly referred to as “solar cells”, with the term “thin-film solar cells” referring to layer systems with small thicknesses of only a few microns that require carrier substrates for adequate mechanical stability. Known carrier substrates include inorganic glass, plastics (polymers), or metals, in particular, metal alloys, and can, depending on the respective layer thickness and the specific material properties, be designed as rigid plates or flexible films.

In view of the technological handling quality and efficiency, thin-film solar cells with a semiconductor layer of amorphous, micromorphous, or polycrystalline silicon, cadmium telluride (CdTe), gallium-arsenide (GaAs), or a chalcopyrite compound, in particular copper-indium/gallium-disulfur/diselenide, abbreviated by the formula Cu(In,Ga)(S,Se)₂, have proved advantageous. In particular, copper-indium-diselenide (CuInSe2 or CIS) is distinguished by a particularly high absorption coefficient due to its band gap adapted to the spectrum of sunlight.

Typically, with individual solar cells, it is possible to obtain only voltage levels of less than 1 volt. In order to obtain a technically useful output voltage, many solar cells are connected to one another in series in a solar module. For this, thin-film solar modules offer the particular advantage that the solar cells can already be connected in series in an integrated form during production of the films. Thin-film solar modules have already been described many times in the patent literature. Reference is made merely by way of example to the printed publications DE 4324318 C1 and EP 2200097 A1.

In the so-called “substrate configuration”, to produce the solar cell, the various layers are applied directly on a substrate that is adhesively bonded to a front-side transparent cover layer to form a weather-resistant laminate. The layer structure between the substrate and the cover layer comprises a back electrode, a front electrode, and a semiconductor layer. Typically, the voltage terminals of the solar cell laminate are guided over the back electrode layer by means of metal strips to the back of the substrate. There, junction boxes are situated that electrically contact the metal strips, for example, via contact clamps.

In practice, for the most part, multiple solar modules are connected in series to the junction boxes by connection cables to form a module string. Typically, each solar module is connected to a freewheeling diode or bypass diode antiparallel to the solar cells, which, in the normal operating state, in which the solar module delivers current, is reverse biased. On the other hand, damage to the solar module can be prevented if, for example, no current is delivered because of shadowing or a module defect, since the current delivered by the other solar modules can flow via the freewheeling diode.

The international patent application WO 2009/134939 A2 describes a solar module, in which a plurality of junction boxes, which have, in each case, a bypass diode, are electrically connected to each other. The two external junction boxes have, in each case, a connection cable for connection to other solar modules. An electrical connection of the junction boxes to each other is done with flat electrical leads in the interior of the solar module. The junction boxes are contacted on their underside, with which they are installed on the back side of the solar module. The German published application DE 102009041968 A1 presents a solar module with junction boxes installed on the underside, which have in each case a bypass diode. Contacting of the junction boxes is done on their underside. An electrical connection of the junction boxes to each other is done by a strip conductor in the interior of the solar module.

In contrast, the object of the present invention consists in advantageously improving conventional solar modules, wherein, in particular, automated manufacture should be simplified and production costs should be reduced. These and other objects are accomplished according to the proposal of the invention by a solar module and a method for production thereof with the characteristics of the coordinated claims. Advantageous embodiments of the invention are indicated by the characteristics of the subclaims.

According to the invention, a solar module having a plurality of solar cells connected in series for photovoltaic power generation is presented. The solar module is preferably a thin-film solar module with thin-film solar cells connected in an integrated form. In particular, the semiconductor layer is made of a chalcopyrite compound which can be, for example, a semiconductor from the group copper-indium/gallium disulfur/diselenide (Cu(In,Ga)(S,Se)₂), for example, copper indium diselenide (CuInSe₂ or CIS) or or related compounds.

The solar cells are typically situated between a first substrate and a second substrate frequently implemented as a cover layer (e.g., cover plate), wherein the two substrates can, for example, contain inorganic glass, polymers, or metal alloys, and, depending on layer thickness and material characteristics, can be designed as rigid plates or flexible films.

The solar module has two (resulting) voltage terminals of opposite polarity, which are in each case guided by a connecting lead to a module outside (i.e., module outside surface) or substrate outside (i.e., substrate outside surface). The two connecting leads are in each case electrically connected on the module outside to a separate connection device, with each connection device situated in a separate connection housing (e.g., junction box or connection box) such that the solar module has two connection housings, in which in each case a connection device is arranged. The two connection housings are in each case fastened on the module outside or module outside surface, onto which the two resulting voltage terminals are guided by the connecting leads.

In the context of the present invention, the term “module outside” means an outward side (i.e., outside surface) of the solar module. The module outside is, at the same time, an outward side (i.e., outside surface) of a substrate (first or second substrate).

In the solar module, the two connecting leads are electrically connected for this purpose to an electrode layer, for example, a back electrode layer, of the connected solar cells. Thus, the two connecting leads are electrically connected to each other by the solar cells connected in series. On the other hand, the two connecting leads end in each case in a separate connection housing. The two connection housings serve for connecting the solar module to an electrical load, in particular for the connection in series of the solar module to other solar modules.

The two connecting leads of the solar module are electrically connected to each other with the interposition of at least one freewheeling or bypass diode connected antiparallel to the solar cells. The freewheeling diode is preferably arranged in one of the two connection housings. Protection of the solar module in the absence of current generation, for example, as a result of shadowing, is obtained by means of the freewheeling diode.

According to the invention, the two connecting leads or the two connection devices, to which the connecting leads are electrically connected, are electrically connected to each other by a ribbon cable arranged between the two connection housings, which is fastened on the module outside (i.e., outside surface of the module) or the substrate outside (i.e., outside surface of the substrate). The ribbon cable is thus not situated in the interior of the solar module (i.e., between the two substrates), but, instead, is arranged on the outside surface of the solar module facing the surroundings.

The ribbon cable enables, in a particularly advantageous manner, a technically less complex integration of the electrical connection between the two connecting leads in an automated process sequence. Since the ribbon cable has a defined geometry, it can be gripped by an automated gripping element in a simple manner for fastening onto the module outside (i.e., outside surface of the module). In addition, a particularly simple and reliable automated fastening of the ribbon cable, for example, by means of adhesive bonding, onto the typically glass module outside or outside surface of the module, is enabled. In contrast to this, an electrical connection of the two connecting leads with a connection cable with a round cross-section would cause significant problems in automation since the geometry of such a connection cable is not defined, and complex and cost-intensive position detection means (e.g., optical sensors) would have to be provided in order to bring the gripping element into position. In addition, the fastening of a connection cable on a glass module outside or outside surface of a module is, due to the relatively small contact surface (for example, by gluing) can be achieved only with significant effort, without being able to rule out the possibility that such fastening would not withstand the high mechanical loads in practice over the long-term. If, on the other hand, such a connection cable were connected only to the two connection housings, the risk would always exist that the connection cable could be misused as a carrying handle.

As a matter of fact, for the first time, with the ribbon cable fastened on the module outside, a simple automation of the electrical connection of the two connecting leads with the interposition of the freewheeling diode can be achieved, by which means time and cost can be saved in industrial series production.

In an advantageous embodiment of the solar module according to the invention, the ribbon cable is surrounded, at least between the two connection housings, by a sheath made of an electrically insulating material. Here, it can be advantageous for the end sections of the ribbon cable arranged inside the associated connection housing to be free for simple electrical contacting. The electrically insulating sheath is situated at least in a section of the ribbon cable that extends from one connection housing to the other connection housing. In particular, the insulating sheathing can even extend into the two connection housings. The ribbon cable is electrically insulated relative to the external surroundings by the sheath.

In the solar module according to the invention, the ribbon cable is fastened on the module outside (i.e., outside surface of the module), which, for example, is accomplished through the fact that the ribbon cable is glued to the module outside.

In another advantageous embodiment of the solar module according to the invention, the ribbon cable is covered by a cover fastened on the module outside (i.e., outside surface of the module) and made of an electrically insulating material. The cover glued for this purpose preferably on the module outside (i.e., outside surface of the module) can fulfill various functions. One function consists in protecting the ribbon cable against mechanical influences to improve long-term durability. Another function can consist in fastening the ribbon cable on the module outside. In this case, a separate fastening of the ribbon cable on the module outside can optionally be dispensed with, but also, on the other hand, provision can be made to fasten the ribbon cable itself onto the module outside in order to obtain a particularly good connection with the module outside.

In an embodiment particularly advantageous from the standpoint of mechanical stress from high temperature fluctuations, the ribbon cable is not fastened on the module outside itself, but, instead, only by way of the covering. It can be further advantageous for the ribbon cable to be electrically connected to the two connecting leads, in particular through the connection devices such that it is not set or fixed in the ribbon plane or in the ribbon direction. In this manner, thermal stresses at the customarily high temperature fluctuations to which the solar module is frequently exposed in practice can be at least substantially reduced.

The ribbon cable enables a particularly simple electrical connection of the connecting leads in the two connection housings. Preferably, the connection housings have, for this purpose, in each case, a contact element, for example, a spring contact element or a clamping contact element, electrically connected to the associated connecting lead that can be brought into electrical contact with one of the two end sections of the ribbon cable. Advantageously, the contact element is implemented so as to automatically come into electrical contact with the ribbon cable at the time of the fastening of the connection housing on the module outside, as a result of which a simple automation of the electrical contacting of the ribbon cable in the connection housings is enabled such that time and costs can be saved with automated module manufacture.

The invention further extends to a method for the automated production of a solar module having a plurality of solar cells connected in series for photovoltaic power generation, wherein the solar module has two voltage terminals of opposite polarity, which are guided in each case by a connecting lead to a module outside or outside module surface, wherein the two connecting leads are electrically connected each case to a separate connection device, wherein each connection device is situated in a separate connection housing. The method comprises the following steps: A step, wherein the two connection housings are in each case fastened to the module outside (i.e., outside surface of the module). A step, wherein the two connecting leads are electrically connected to each other with the interposition of a freewheeling diode arranged in particular in one of the two connection housings, wherein for the electrical connection of the two connecting leads, a ribbon cable arranged between the two connection housings is fastened on the module outside (i.e., outside surface of the module). For example, the ribbon cable is glued for this purpose to the module outside (i.e., outside surface the module). For example, a cover covering the ribbon cable is fastened on the module outside (i.e., outside surface of the module), wherein it is, in particular, possible for the ribbon cable to be fastened to the module outside exclusively by the cover. It can further be advantageous for contact elements to automatically be brought into electrical contact with the ribbon cable at the time of the fastening of the connection housing to the module outside.

### BRIEF DESCRIPTION OF THE DRAWINGS

The invention is now explained in detail using exemplary embodiments and with reference to the accompanying figures. In the figures, identical or identically functioning elements are identified by the same reference characters. They depict:

FIG. 1 a schematic view of the structure of the solar module according to the invention;

FIG. 2 a schematic cross-sectional view of the solar module of FIG. 1;

FIG. 3 a schematic view to illustrate the ribbon cable of the solar module of FIG. 1;

FIG. 4 a schematic view to illustrate the contacting of the ribbon cable in a junction box of the solar module of FIG. 1;

FIG. 5-6 schematic views to illustrate variants of the ribbon cable of FIG. 3;

FIG. 7-8 schematic views to illustrate variants of the connecting leads in the solar module of FIG. 1.

### DETAILED DESCRIPTION OF THE DRAWINGS

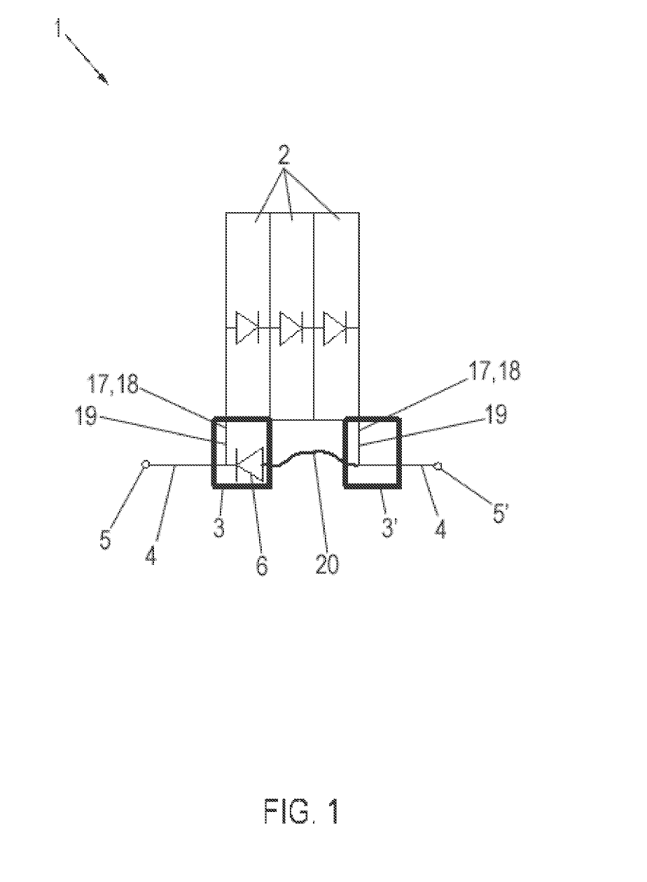

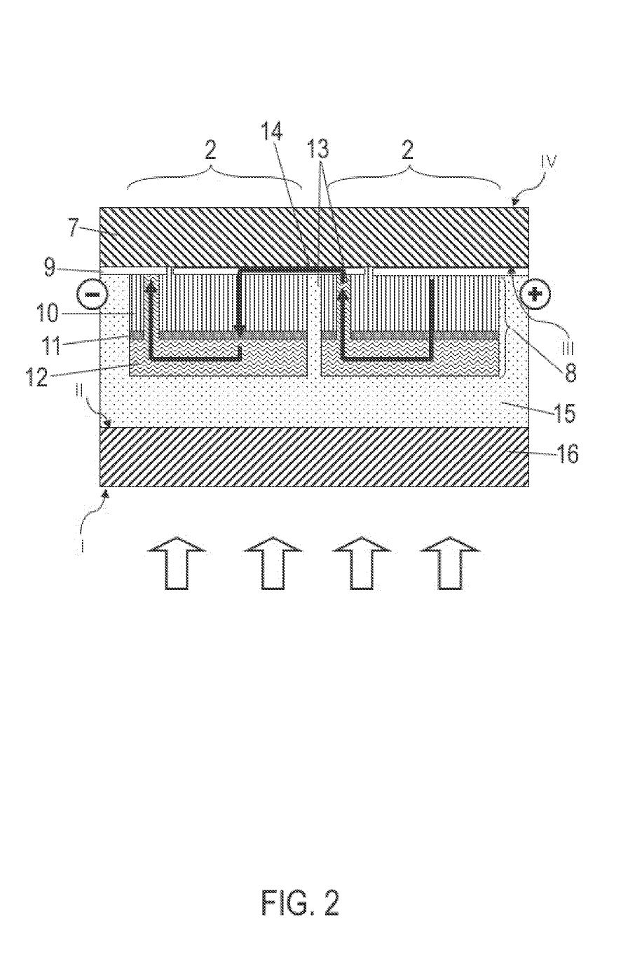

Reference is first made to FIGS. 1 and 2, in which the structure of a solar module according to the present invention identified as a whole by the reference number 1 is illustrated. According to them, the solar module 1, which is, here, for example, a thin-film solar module, comprises a plurality of solar cells 2 connected to each other in series in an integrated form, which are in each case marked with a diode symbol. The solar module 1 is based here, for example, on the so-called “substrate configuration”, which is explained in detail in conjunction with FIG. 2. FIG. 2 presents, by way of example, two (thin-film) solar cells 2, with the understanding that the solar module usually has a large number (e.g., ca. 100) of solar cells 2.

The solar module 1 comprises an electrically insulating substrate 7 (designated in the introduction to the description as “first substrate”) with a layer structure mounted thereon to form a photovoltaically active absorber layer 8. The layer structure is arranged on the light-entry front side (III) of the substrate 7. The substrate 7 is made here, for example, of glass with relatively low permeability to light, with it equally possible to use other insulating materials with adequate strength as well as inert behavior relative to the process steps performed. The layer structure comprises a back electrode layer 9 arranged on the front side (III) of the substrate 7. The back electrode layer 9 contains, for example, a layer of an opaque metal such as molybdenum and is applied on the substrate 7, for example, by cathode sputtering. The back electrode layer 9 has, for example, a layer thickness of roughly 1 μm. In another embodiment, the back electrode layer 9 comprises a layer stack of different individual layers.

The photovoltaically active absorber layer 8, whose band gap is preferably capable of absorbing the greatest possible fraction of sunlight, is deposited on the back electrode layer 9. The photovoltaically active absorber layer 8 contains a p-doped semiconductor layer 10, for example, a p-conductive chalcopyrite semiconductor, such as a compound from the group copper indium diselenide (CuInSe₂), in particular Cu(In,Ga)(S,Se)₂. The semiconductor layer 10 has, for example, a layer thickness of 500 nm to 5 μm and, in particular, of roughly 2 μm. A buffer layer 11, which contains here, for example, a single layer of cadmium sulfide (CdS) and a single layer of intrinsic zinc oxide (i-ZnO), is deposited on the semiconductor layer 10. A front electrode layer 12 is applied on the buffer layer 11, for example, by vapor deposition. The front electrode layer 12 is transparent (“window layer”) to radiation in the spectral range sensitive for the semiconductor layer 11, to ensure only a slight fluctuation of the incident sunlight. The transparent front electrode layer 12 can, in general, be referred to as a TCO layer (TCO=transparent conductive oxide and is based on a doped metal oxide, for example, n-conductive, aluminum-doped zinc oxide (AZO). A pn-heterojunction, i.e., a sequence of layers of the opposing conductor type, is formed by the front electrode layer 12, the buffer layer 11, and the semiconductor layer 10. The layer thickness of the front electrode layer 12 is, for example, 300 nm.

The layer system is divided using methods known per se for production of a (thin-film) solar module 1 into individual photovoltaically active regions, i.e., solar cells 2. The division is carried out by incisions 13 using a suitable patterning technology such as laser writing and machining, for example, by drossing or scratching. The individual solar cells 2 are connected to each other in series via an electrode region 14 of the back electrode layer 9.

The solar module 1 has, for example, 100 solar cells 2 connected in series and a open-circuit voltage of 56 V. In the example depicted here, both the resultant positive (+) and the resultant negative (−) voltage terminal of the solar module 1 are guided over the back electrode layer 9 and electrically contacted there, as is explained in detail below.

For protection against environmental influences, an intermediate layer 15, which contains, for example, polyvinyl butyral (PVB) or ethylene vinyl acetate (EVA), is applied on the front electrode layer 12. The thickness of the intermediate layer 15 is, for example, 0.76 mm. In addition, the layer structure composed of substrate 7, back electrode layer 9, and photovoltaically active absorber layer 8 is sealed over the intermediate layer 15 with a cover pane 16 (designated in the introduction to the description as “second substrate”), which is glued to its back side (II). The cover pane 16 is transparent to sunlight and contains, for example, hardened, extra-white, low-iron glass. The cover pane 16 has, for example, an area of 1.6 m×0.7 m. The solar cells 2 can be irradiated by light incident on the front side (I) of the cover pane 16, which is indicated in FIG. 2 by the arrows. The front side (I) or front surface of the cover pane 16 and the back side (IV) or back surface of the substrate 7 form the module outside or outside surface of the module.

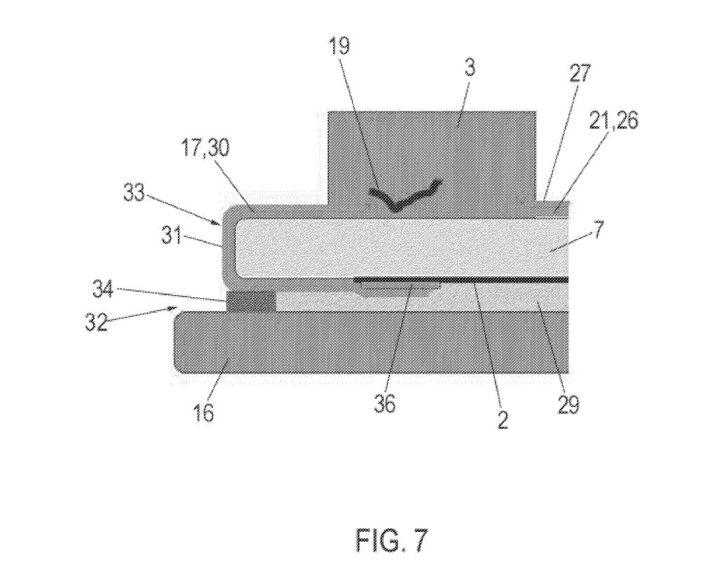

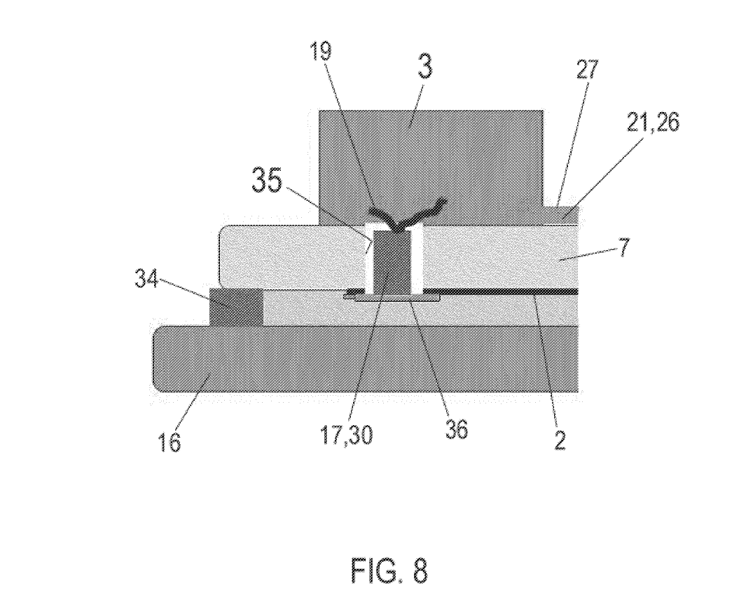

It is also expedient for the edge region between substrate 7 and cover plate 16 to be sealed circumferentially with an edge sealing 34 as a vapor diffusion barrier, preferably with a plastic material, for example, poly isobutylene, to protect the corrosion sensitive photovoltaically active absorber layer 8 against atmospheric oxygen and moisture. The edge sealing 34 is discernible in FIGS. 7 and 8. The entire solar module 1 is fastened, for installation at the site of use, in a hollow-chamber aluminum frame (not shown).

In the solar module 1, the two resultant voltage terminals (+, −) are guided by two connecting leads 17 onto the back side (IV) or back surface of the substrate 7, which are illustrated in FIGS. 1, 7, and 8.

Reference is now made to FIG. 7, in which a cross-section through the solar module 1 in the region of a connecting leads 17 is depicted. The solar module 1 has, in the region of the two connecting leads 17, an identical structure.

According to this figure, the connecting lead 17 comprises a strip-shaped metal foil 30, for example, made of aluminum, with a thickness of, for example, 0.1 mm and a width of, for example, 20 mm. The metal foil 30 is glued (here, for example, on one side) to an insulating film 31 made from an electrically insulating material, for example, polyimide, with the insulating film 31 arranged on the outward side, i.e., on the side of the foil lead 17 facing away from the substrate 7. In an alternative embodiment, the connecting lead 17 comprises a tinned copper strip. It would be equally possible for the strip-shaped metal foil 30 to be bonded on both sides to an insulating film 31. The insulating film 31 is, for example, glued onto the metal foil 30. It is also conceivable to laminate the metal foil 30 into two insulating films 31.

The metal foil 30 of the two connecting leads 17 is electrically connected to a strip-shaped electrical conductor, a so-called “busbar” 36. The two busbars 36 contact in each case a resultant voltage terminal (+, −) of the solar module 1 (here, for example, formed by the back electrode layer 9) and extend only in the region of the plane of the back electrode layer 9. The busbars 36 thus serve for the electrical connection of the two voltage terminals to the connecting leads 17.

Each busbar 36 is implemented here, for example, as metal foil, in particular aluminum foil. The metal foil 30 of the two connecting leads 17 and the busbar 36 electrically connected thereto can be implemented in two parts and can be different from one another; in particular, they can be made of materials different from one another. However, alternatively, it is also possible for the metal foil 30 of the two connecting leads 17 and the busbar 36 electrically connected thereto to be a single part or one-piece metal foil such that the busbar 36 is merely a foil section of the metal foil 30 of the connecting lead 17.

The two busbars 36 are electrically conductively connected to the back electrode layer 9, for example, by welding, bonding, soldering, or gluing with an electrically conductive adhesive. In the case of an aluminum foil, the electrical connection to the back electrode layer 9 is preferably done by ultrasonic bonding.

In the example depicted in FIG. 7, the two connecting leads 17 are in each case guided on the lateral module edge 32 out of the laminate of substrate 7 and cover pane 16, around the substrate edge 33 of the substrate 7, and all the way to the back side (IV) of the substrate 7.

The two connecting leads 17 have in each case a connection point 18 for electrical contacting, which are arranged, for example, on the back side (IV) of the substrate 7 at a distance of roughly 20 mm from its side edge (substrate edge 33), with the understanding that the connection points 18 can, in principle, be arranged at any points on the back side (IV) of the substrate 7.

The electrical contacting of the two connecting leads 17 at the contact points 18 is done in each case through a first connection device 19 in a junction box 3, which has, for this purpose, an electrical contact element, for example, a spring or clamp contact element. FIG. 7 depicts, by way of example, a spring contact element that contacts the metal foil 30 of the connecting lead 17. Alternatively, an electrical connection by soldering, gluing with a conductive adhesive, or ultrasonic bonding, for example, would also be possible. For conducting leads 17 made of aluminum it is expedient to tin the connection points 18 in order to improve the electrical conductivity. On the other hand, the connection points 18 need not be bare metal, but can, instead, equally be coated with a protective layer of a paint or a plastic film to protect the metal contact surface against oxidation and corrosion during the production process. The protective layer can be penetrated for electrical contacting with an object, for example, a contact pin or a contact needle. It is also conceivable to manufacture the protective layer from a bondable and peelable plastic film that is removed before the actual electrical contacting with the contact element.

The contacting of the connection points 18 of the two connecting leads 17 is done in the junction boxes 3 that are, for example, made of plastic and produced in the injection molding process. The two junction boxes 3 are fastened on the back side (IV) or outside surface of the substrate 7, for example, by gluing, which enables simple and fast automated assembly. The bonding of the junction boxes 3 to the substrate 7 can, for example, be done with an acrylic adhesive or a polyurethane adhesive. In addition to a simple and durable connection, these adhesives fulfill a sealing function and protect the electrical components contained against moisture and corrosion. The interior of the junction boxes 3 can also be filled, at least partially, with a sealant, for example, poly isobutylene, to increase the electrical breakdown resistance and to reduce the risk of penetration of moisture and the leakage currents associated therewith.

FIG. 8 illustrates an alternative embodiment of the solar module 1 in the region of the connecting lead 17. To avoid unnecessary repetitions, only the differences relative to FIG. 7 are explained; and, otherwise, reference is made to the statements made there. Accordingly, an opening 35, implemented here, for example, as a borehole is provided for each connecting lead 17 in each case in the substrate 7, through which opening the connecting lead 17 is guided to the back side (IV) or outside surface of the substrate 7. The connecting lead 17 has a metal foil 30, but no insulating sheath 31.

As depicted in FIG. 1, the two junction boxes 3 have in each case a connection cable 4 with a terminal connection 5 that is electrically connected to the first connection device 19. The solar module 1 can be connected on the two terminal connections 5 to an electrical load, for example, an inverter. The two terminal connections 5 can serve in particular for the connection in series of the solar module 1 to other solar modules (not shown).

A freewheeling diode 6, which is connected in series to the two connecting leads 17 antiparallel to the forward current direction of the solar cells 2 of the solar module 1, is arranged in one of the two junction boxes 3. By means of the freewheeling diode 6, the solar module 1 is prevented from being damaged by pole reversal, for example, in the case of shadowing or a module defect. The electrical connection between the two connecting leads 17 or the two first connection devices 19 is illustrated schematically in FIG. 1 by an electrical wire 20.

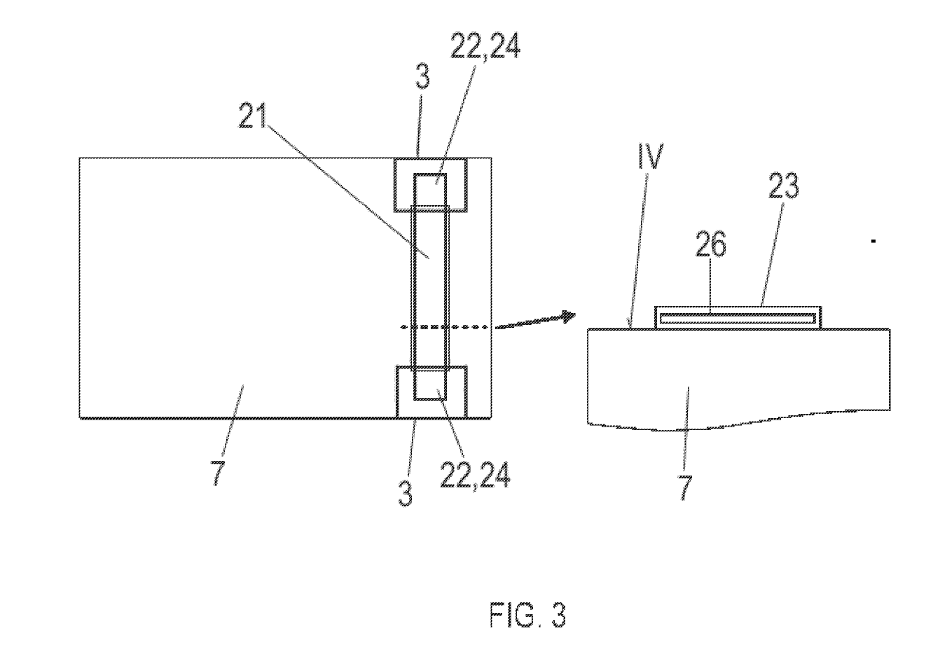

As depicted in FIG. 3, the electrical connection between the connecting leads 17 or the two first connection devices 19 comprises a ribbon cable 21 arranged between the two junction boxes 3, which extends with its two end sections 22 in each case into the junction boxes 3. FIG. 3 depicts a view of the back side (IV) or outside surface of the substrate 7 as well as a cross-section through the substrate 7 in the region of the ribbon cable 21, with the section line indicated in the top view.

The ribbon cable 21 has a defined geometric shape such that it can be gripped relatively simply by a gripping element for assembly. As is discernible from the cross-section, the ribbon cable 21 comprises an electrically conductive metal strip 26 that is surrounded by an insulating sheath 23 made of an electrically insulating material, with the two end sections 22 of the metal strip 26 lying freely inside the junction boxes 3. The metal strip 26 is, for example, an aluminum strip or a tinned copper strip of a thickness of, for example, 10 to 30 μm, a width of, for example, 50 mm, and a length of, for example, 60 cm. The metal strip 26 bonded to an electrically insulating film, made, for example, of polyimide, with the electrically insulating film situated on all sides, in particular even on the side of the ribbon cable 21 turned toward the substrate 7. The ribbon cable 21 is glued with its wide surface onto the back side (IV) or back outside surface of the substrate 7 by an adhesive layer 29, which enables simple and fast automated assembly on the substrate 7. The bonding of the ribbon cable 21 can be done, for example, with an acrylic adhesive or a polyurethane adhesive. It is also conceivable to adhesively bond the ribbon cable 21 onto the substrate 7 with a two-sided adhesive strip. Depending on the manner of electrical contacting, its end sections 22 can be bonded to the substrate 7 or even be freely movable relative to the substrate 7. As a result of the large adhesive area, the ribbon cable 21 can be fastened reliably and with long-term stability on the substrate 7.

Generally speaking, the ribbon cable 21 is distinguished by a very high aspect ratio (width-to-thickness ratio) such that even with a very flat embodiment, a low electrical resistance of, for example, less than 10 mΩ is realized. With a current of, for example, 3 A, this would result in a voltage loss of, for example, 30 mV, corresponding to an efficiency loss of, for example, ca. 0.06%.

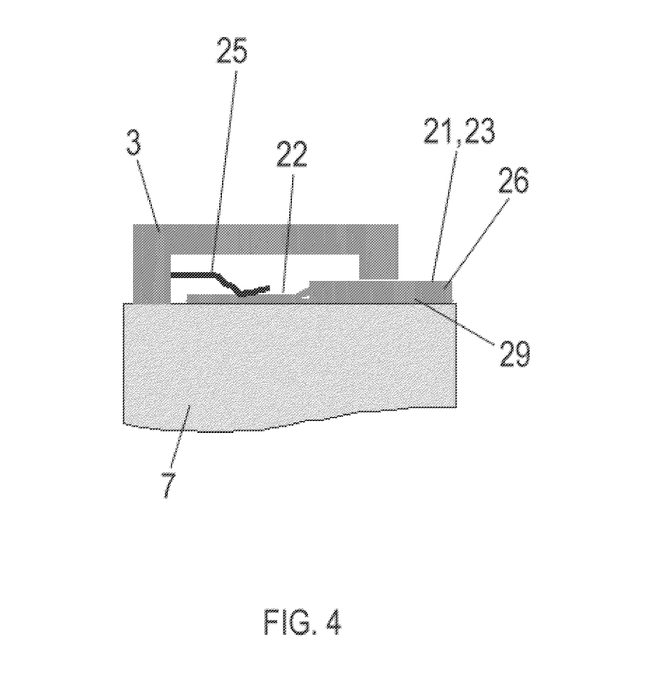

The two end sections 22 of the ribbon cable 21 are situated in each case completely inside the junction boxes 3, with the insulating sheath 23 extending into the junction boxes 3. The end sections 22 of the metal strip 26 serve as connection points 24 for electrical contacting, which is shown in detail in FIG. 4 by means of a cross-sectional depiction in the region of one end section 22. FIG. 4 depicts a section in the region of one end section 22, with the solar module 1 having an identical structure in the region of the two end sections 22.

As is discernible from FIG. 4, electrical contacting of the two end sections 22 is done in each case through a second connection device 25 with an electrical contact element made from an electrically conductive material, here, for example, a spring contact element that comes to rest under spring loading against the surface of the metal strip 26. With the use of such a spring contact element, the end sections 22 can in each case be fastened (glued) onto the substrate 7. The two spring contact elements 25 are electrically connected, with the interposition of the freewheeling diode 6, to the two first connection devices 19, on which the two connecting leads 17 are connected. In particular, the two second connection devices 25 can be implemented for the electrical connection of the metal strip 26 of the ribbon cable 21 and the two first connection devices 25 for the electrical connection of the metal foil 30 of the connecting leads 17 as components of a common connection device.

A particular advantage of the use of the connection device implemented as a spring contact element resides in the fact that each spring contact element can be implemented such that it automatically comes into contact with the metal strip 26 or metal foil 30 by means of the (automated) assembly of the junction box 3 on the substrate 7, by which means the automated manufacture of the solar module 1 is facilitated. Alternatively, however, it would also be possible to use a clamping contact element or a contact element (e.g., wire) to be bonded by soldering, by gluing with a conductive adhesive, or by ultrasonic bonding to the metal strip 26.

If the metal strip 26 is made of aluminum, is expedient to tin the connection points 24 to improve the electrical conductivity. It is understood that the connection points 24 need not be bare metal, but, instead, can be coated with a protective layer of paint or plastic film to protect the metal contact surface against oxidation and corrosion during the production process. The protective layer can be penetrated for electrical contacting with an object, for example, a contact pin or a contact needle. It is also conceivable to manufacture the protective layer from a bondable and peelable plastic film that is removed before the actual electrical contacting.

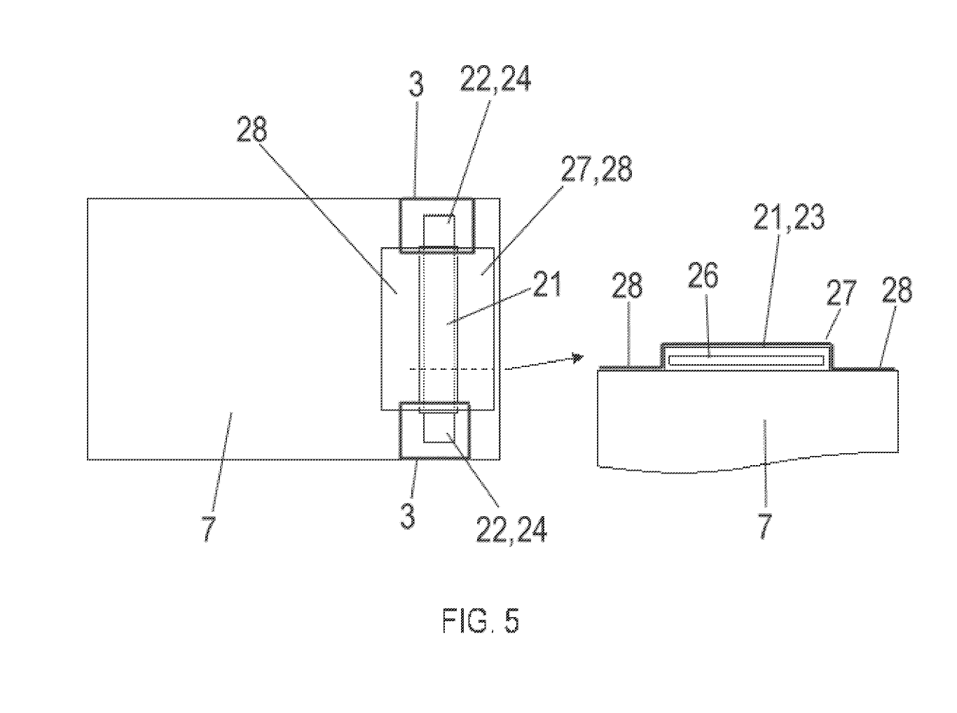

FIG. 5 depicts a variant of the solar module 1, using a corresponding top view and sectional view. Here, a cover film 27 that is arranged over the ribbon cable 21 already glued to the substrate 7 and is bonded to the back side (IV) of the substrate 7 is additionally provided. The cover film 27 is thus not situated on the side of the ribbon cable 21 turned toward the substrate 7. The cover film 27 is wider than the ribbon cable 21 and has two laterally protruding film regions 28. The cover film 27 can be bonded to the ribbon cable 21. In an alternative design, the cover film 27 is glued only to the substrate 7 and rests against the ribbon cable 21 but without actual bonding.

The cover film 27 is made of an electrically insulating material, for example, plastic. As illustrated in FIG. 5, the cover film 27 can extend into the junction boxes 3, with the end sections 22 remaining free for electrical contacting. The cover film 27 serves for mechanical protection of the ribbon cable 21, with the fastening of the ribbon cable 21 on the substrate 7 also reinforced.

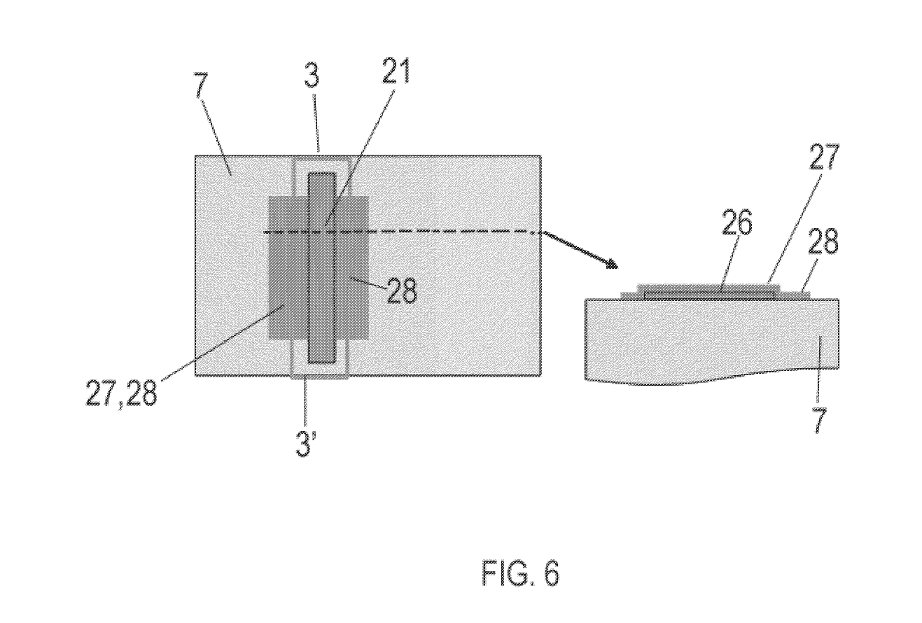

FIG. 6 depicts another variant of the solar module 1, using a top view and a sectional view. This variant differs from the variant depicted in FIG. 5 only in that the ribbon cable 21 has no insulating sheath 21 and is not glued to the substrate 7. A fastening of the ribbon cable 21 or metal strip 26 on the substrate 7 is done only by the film cover 27 bonded to the substrate 7. In a possible embodiment, the cover film 27 is glued to the metal strip 26. In an alternative embodiment, the cover film 27 is not glued to the metal strip 26. In the latter case, it is advantageous if the two end sections 22 are movably contacted in each case in the junction boxes 3 at least in the directions of the strip planes of the metal strips 26 such that the metal strip 26 can complete thermal volume changes without generating mechanical stresses in the process. This can be achieved, for example, through electrical contacting by the two spring contact elements 25. By means of these measures, long-term durability can be improved.

With the variant depicted in FIG. 6, the cover film 27 of the ribbon cable 21 has a greater width, i.e., the dimension of the two laterally protruding film regions 28 is greater than that of the ribbon cable 21 in FIG. 5. Alternatively, it would also be conceivable for the width of the cover film 27 to be smaller than that of the ribbon cable 21 of FIG. 5.

The invention makes available a solar module, in particular a thin-film solar module, wherein the connecting leads for connection of the solar cells to the connection devices are electrically connected to each other in the junction boxes by a ribbon cable with the interposition of a freewheeling diode. The ribbon cable enables a technically simple to realize automated fastening onto the substrate, wherein the ribbon cable can, for example, be reliably and certainly connected to the substrate by adhesive bonding.

### LIST OF REFERENCE CHARACTERS

1 solar module

2 solar cell

3 junction boxes

4 connection cable

5 terminal connection

6 freewheeling diode

7 substrate

8 absorber layer

9 back electrode layer

10 semiconductor layer

11 buffer layer

12 front electrode layer

13 incision

14 electrode region

15 intermediate layer

16 cover pane

17 connecting lead

18 connection point

19 first connection device

20 wire

21 ribbon cable

22 end section

23 insulating sheath

24 connection point

25 second connection device

26 metal strip

27 cover film

28 film region

29 adhesive layer

30 metal foil

31 insulating film

32 module edge

33 substrate edge

34 edge sealing

35 opening

36 busbar

1. A solar module having a plurality of solar cells connected in series for photovoltaic power generation, comprising:
two voltage terminals of opposite polarity, which are each guided by a connecting lead to an outside surface of the module,
wherein:
the connecting leads are each electrically connected to a separate connection device, each connection device being situated in a separate connection housing,
the connection housings are each fastened to the outside surface of the module,
the connecting leads are electrically connected to each other with an interposition of at least one freewheeling diode, and
the connection devices are electrically connected to each other by a ribbon cable arranged between the connection housings, the cable being fastened to the outside surface of the module.

2. The solar module according to claim 1, wherein the ribbon cable is surrounded, at least between the two connection housings, by a sheath made of an electrically insulating material.

3. The solar module according to claim 1, wherein the ribbon cable is adhesively bonded to the outside surface of the module.

4. The solar module according to claim 1, wherein the ribbon cable is covered by a cover made of an electrically insulating material and fastened to the outside surface of the module.

5. The solar module according to claim 4, wherein the cover is glued to the outside surface of the module.

6. The solar module according to claim 4, wherein the cover is not connected to the ribbon cable.

7. The solar module according to claim 6, wherein the ribbon cable is electrically connected to the two connecting leads such that it is not fixed in a direction of the ribbon.

8. The solar module according to claim 1, wherein the connection devices each comprise a contact element, in particular a spring contact element, for the electrical contacting of the ribbon cable.

9. The solar module according to claim 8, wherein the contact element is implemented so as to automatically come into electrical contact with the ribbon cable at the time of the fastening of the connection housing to the outside surface of the module.

10. A method for the automated production of a solar module having a plurality of solar cells connected in series for photovoltaic power generation, wherein the solar module has two voltage terminals of opposite polarity, which are each guided by a connecting lead to an outside surface of the module, wherein the two connecting leads are each electrically connected to a separate connection device, and wherein each connection device is situated in a separate connection housing, the method comprising the steps of:
fastening each of the two connection housings to the outside surface of the module, and
electrically connecting the two connection devices to each other with an interposition of a freewheeling diode by a ribbon cable arranged between the two connection housings, wherein the ribbon cable is fastened to the outside surface of the module.

11. The method according to claim 10, wherein the ribbon cable is adhesively bonded to the outside surface of the module.

12. The method according to claim 10, wherein a cover covering the ribbon cable is fastened to the outside surface of the module.

13. The method according to claim 12, wherein the ribbon cable is fastened to the outside surface of the module by the cover.

14. The method according to claim 11, wherein at a time of the fastening of the connection housings to the outside surface of the module, contact elements are automatically brought into electrical contact with the ribbon cable.
